(19) United States
(12) Patent Application Publication
(10) Pub. No.: US 2008/0242088 A1
(43) Pub. Date: Oct. 2, 2008

(54) METHOD OF FORMING LOW RESISTIVITY COPPER FILM STRUCTURES

(75) Inventor: Kenji Suzuki, Guilderland, NY (US)

Correspondence Address: WOOD, HERRON & EVANS, LLP (TOKYO ELECTRON), 2700 CAREW TOWER, 441 VINE STREET, CINCINNATI, OH, 45202, US

(73) Assignee: TOKYO ELECTRON LIMITED, Tokyo (JP)

(21) Appl. No.: 11/693,298

(22) Filed: Mar. 29, 2007

(51) Int. Cl. H01L 21/44

(52) U.S. Cl. 438/687

(57) ABSTRACT

A method for forming low (electrical) resistivity Cu film structures by depositing a metal nitride barrier film on a substrate, depositing a Ru film on the metal nitride barrier film, depositing a Cu seed layer on the Ru film, and depositing bulk Cu metal on the Cu seed layer. The method further includes heat treating the Ru film prior to the Cu seed layer deposition, heat treating the bulk Cu metal, or heat treating both the Ru film prior to the Cu seed layer deposition and the bulk Cu metal. According to one embodiment, a method is provided for forming low resistivity Cu interconnect structures for integrated circuits.

### FIELD OF THE INVENTION

The invention relates to integrated circuits, and more particularly to processing methods for forming low (electrical) resistivity copper (Cu) film structures containing ruthenium (Ru) films.

### BACKGROUND OF THE INVENTION

An integrated circuit contains various semiconductor devices and a plurality of conducting metal paths that provide electrical power to the semiconductor devices and allow these semiconductor devices to share and exchange information. Within an integrated circuit, metal layers are stacked on top of one another using intermetal or interlayer dielectric layers that insulate the metal layers from each other. Normally, each metal layer must form an electrical contact to at least one additional metal layer. Such electrical contact is achieved by etching a hole (i.e., a via) in the interlayer dielectric that separates the metal layers, and filling the resulting via with a metal to create an interconnect structure. Metal layers typically occupy etched pathways in the interlayer dielectric. A “via” normally refers to any micro-feature such as a hole, line or other similar feature formed within a dielectric layer that provides an electrical connection through the dielectric layer to a conductive layer underlying the dielectric layer. Similarly, micro-features containing metal layers connecting two or more vias are normally referred to as trenches.

A long-recognized objective in the constant advancement of integrated circuit (IC) technology is the scaling down of IC dimensions. Such scale down of IC dimensions reduces area capacitance and is critical to obtaining higher speed performance of ICs. Moreover, reducing the area of an IC die leads to higher yield in IC fabrication. These advances are driving forces to constantly scale down IC dimensions. An increase in device performance is normally accompanied by a decrease in device area or an increase in device density. An increase in device density requires a decrease in via dimensions used to form interconnects, including a larger aspect ratio (i.e., depth to width ratio). As the minimum feature dimensions on patterned substrates (wafers) steadily decreases, several consequences of this downward scaling are becoming apparent. As the width of metal lines are scaled down to smaller submicron and even nanometer dimensions, electromigration failure, which may lead to open and extruded metal lines, is now a well-recognized problem. Moreover, as dimensions of metal lines further decrease, metal line resistivity increases substantially, and this increase in line resistivity may adversely affect circuit performance.

The introduction of copper (Cu) metal into multilayer metallization schemes for manufacturing integrated circuits is enabled by the damascene Cu plating process and is now extensively used by manufacturers of advanced microprocessors and application-specific circuits. However, Cu cannot be put in direct contact with dielectric materials since Cu has poor adhesion to the dielectric materials and Cu is known to easily diffuse into common integrated circuit materials such as silicon and dielectric materials where Cu is a mid-bandgap impurity. Furthermore, oxygen can diffuse from an oxygen-containing dielectric material into Cu, thereby decreasing the electrical conductivity of the Cu metal. Therefore, a diffusion barrier material is formed on dielectric materials and other materials in the integrated circuits to surround the Cu and prevent diffusion of the Cu into the integrated circuit materials.

Cu plating on interconnect structures usually requires a nucleation or seed layer that is deposited on the diffusion barrier. The seed layer is preferably conformally deposited over the interconnect structure prior to Cu plating. As the line width of interconnect structures is continually decreased, the thickness of the diffusion barrier and seed material needs to be reduced to minimize the volume of the diffusion barrier material within an interconnect feature containing the Cu metal fill. Minimizing the volume of the diffusion barrier material in turn maximizes the volume of the Cu metal fill. As is known to one of ordinary skill in the art, diffusion barrier materials generally have higher electrical resistivity than the Cu metal fill. Therefore, maximizing the volume of the Cu metal fill and minimizing the volume of the diffusion barrier material results in minimizing the electrical resistivity of the interconnect structure.

A tantalum nitride/tantalum (TaN/Ta) bilayer is commonly used as a diffusion barrier/adhesion layer for Cu metallization since the TaN barrier layer adheres well to oxides and provides a good barrier to Cu diffusion and the Ta adhesion layer wets well to both TaN on which it is formed and to the Cu metal formed over it. However, Ta is normally deposited by sputtering or plasma processing methods which are unable to provide conformal coverage over high aspect ratio micro-features. Ruthenium (Ru) has been suggested to replace the Ta adhesion layer since it may be conformally deposited and adheres well to TaN and to Cu. However, Cu metallization structures containing Ru films have generally showed higher Cu resistivity than those containing the traditional TaN/Ta bilayers.

Therefore, new processing methods are needed for forming low resistivity film structures containing Cu and Ru.

### SUMMARY OF THE INVENTION

A method is provided for forming low resistivity film structures and interconnect structures for integrated circuits. The structures contain a metal nitride barrier film on a substrate, a Ru film on the metal nitride barrier film, and bulk Cu metal on the Ru film.

According to one embodiment of the invention, the method includes depositing a metal nitride barrier film on a substrate, depositing a Ru film on the metal nitride barrier film, heat treating the Ru film at a temperature between about 200° C. and about 400° C. in the presence of a first inert gas, H₂ gas, or a combination of the first inert gas and H₂ gas, depositing a Cu seed layer on the heat treated Ru film, and depositing bulk Cu metal on the Cu seed layer. According to another embodiment of the invention, the method further includes heat treating the bulk Cu metal at a temperature between about 200° C. and about 400° C. in the presence of H₂ gas or a combination of a second inert gas and H₂ gas.

According to another embodiment of the invention, the method includes depositing a metal nitride barrier film on a substrate, depositing a Ru film on the metal nitride barrier film, depositing a Cu seed layer on the Ru film, depositing bulk Cu metal on the Cu seed layer, and heat treating the bulk Cu metal at a temperature between about 200° C. and about 400° C. in the presence of H₂ gas or a combination of an inert gas and H₂ gas.

According to yet another embodiment of the invention, a method is provided for forming a low resistivity interconnect structure. The method includes providing a substrate containing a micro-feature opening formed within a dielectric material, depositing a metal nitride barrier film on the substrate, depositing a Ru film on the metal nitride barrier film, depositing a Cu seed layer on the Ru film by sputter depositing, filling the micro-feature opening with bulk Cu metal, and heat treating the bulk Cu metal at a temperature between about 200° C. and about 400° C. in the presence of H₂ gas or a combination of a first inert gas comprising a noble gas or N₂ and a H₂ gas. According to another embodiment, the Ru film may be heat treated at a temperature between about 200° C. and about 400° C. in the presence of a second inert gas comprising a noble gas or N₂, H₂ gas, or a combination of the second inert gas and H₂ gas, prior to depositing the Cu seed layer.

### BRIEF DESCRIPTION OF THE DRAWINGS

In the drawings:

FIGS. 1A-1E schematically show cross-sectional views of forming a low resistivity Cu structure according to an embodiment of the invention;

FIGS. 2A and 2B illustrate the relationship between Cu resistivity and Cu(111) grain size;

FIG. 3 summarizes the relationship between Cu resistivity and Cu(111) grain size from FIGS. 2A and 2B;

FIGS. 4A and 4B show Ta/Cu and Ru/Cu film stress versus temperature;

FIG. 5 shows resistivity of bulk Cu films in tabular form for different film structures;

FIGS. 6A-6C are process flow diagrams for forming low resistivity Cu film structures according to embodiments of the invention;

FIGS. 7A-7F schematically show cross-sectional views of forming low resistivity Cu interconnect structures according to embodiments of the invention; and

FIGS. 8A and 8B schematically show cross-sectional views of additional interconnect structures according to embodiments of the invention.

### DETAILED DESCRIPTION OF SEVERAL EMBODIMENTS OF THE INVENTION

Embodiments of the invention provide methods for forming low resistivity Cu structures containing Ru films. The methods include post-deposition heat treatments of materials and films that make up interconnect structures of integrated circuits. The current inventors have studied different process variations and heat treatments that affect Cu resistivity and Cu(111) grain size in bulk Cu metal for TaN/Ru/Cu film structures, in order to achieve Cu resistivity that is comparable or equal to conventional TaN/Ta/Cu film structures. This enables device manufacturers to replace TaN/Ta/Cu film structures with TaN/Ru/Cu film structures in integrated circuits. Ru films can be deposited with superior conformality over high-aspect ratio structures compared to Ta films, and the Ru films may be annealed to higher temperatures than the corresponding Ta films while providing low Cu resistivity and good electromigration properties.

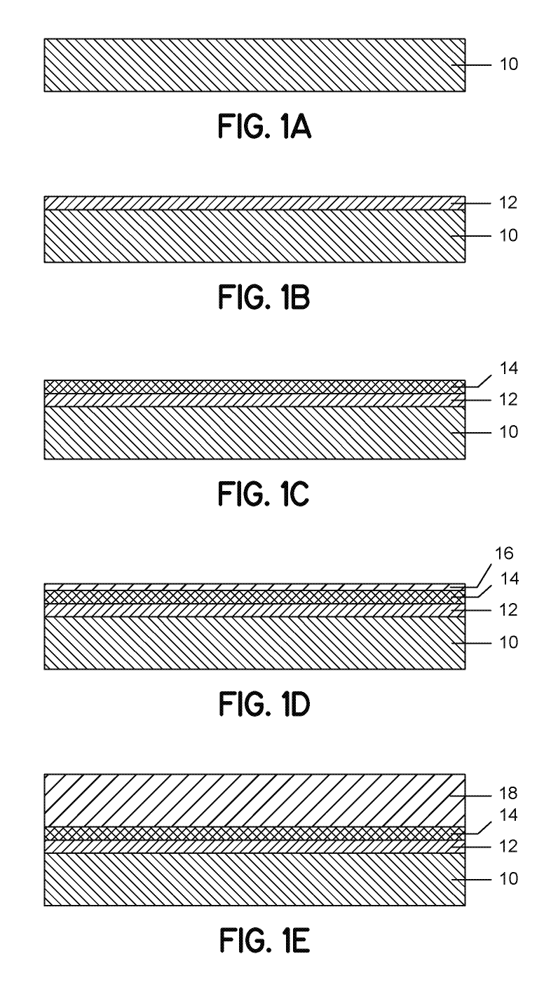

FIGS. 1A-1E schematically show cross-sectional views of forming a low resistivity Cu structure according to an embodiment of the invention. FIG. 1 A shows a substrate 10, for example a Si substrate or a dielectric material. The dielectric material may contain SiO₂, SiON, SiN, or a low dielectric constant (low-k) material having a dielectric constant less than that of SiO₂ (k˜3.9). Common low-k materials can contain simple or complex compounds of Si, O, N, C, H, or halogens, either as dense or porous materials.

FIG. 1B schematically shows a metal nitride barrier film 12 formed on the substrate 10. The metal nitride barrier film 12 can, for example, contain TaN, TiN, or WN, or a combination thereof. The combination may include two or more separate TaN, TiN, and WN films, for example TaN/TiN or TaN/WN. A thickness of the metal nitride barrier film 12 can, for example, be between about 1 nm (nm=10⁻⁹ m) and about 10 nm, or between about 2 nm and about 5 nm, for example about 4 nm. The metal nitride barrier film 12 may be deposited by a variety of different deposition methods known by one of ordinary skill in the art, including, but not limited to, chemical vapor deposition (CVD), pulsed CVD, plasma-enhanced CVD (PECVD), atomic layer deposition (ALD), plasma-enhanced ALD (PEALD), or sputtering methods. According to one embodiment of the invention, the metal nitride barrier film 12 may be deposited by a non-plasma process, e.g., CVD, pulsed CVD, or ALD, to avoid possible plasma damage during processing. Furthermore, non-plasma processes are usually better able to deposit conformal films than plasma processes, especially for patterned substrates containing high aspect ratio structures.

A wide variety of Ta—, Ti—, and W-containing precursors may be utilized for depositing TaN, TiN, and WN films for the metal nitride barrier film 12. Representative examples of Ta-containing precursors include Ta(NMe₂)₅(pentakis(dimethylamido)tantalum, PDMAT), Ta(NEtMe)₅(pentakis(ethylmethylamido)tantalum, PEMAT), (tBuN)Ta(NMe₂)₃ (tert-butylimido tris(dimethylamido)tantalum, TBTDMT), (tBuN)Ta(NEt₂)₃(tert-butylimido tris(diethylamido)tantalum, TBTDET), (tBuN)Ta(NEtMe)₃(tert-butylimido tris(ethylmethylamido)tantalum, TBTEMT), (EtMe₂CN)Ta(NMe₂)₃(tert-amylimido tris(dimethylamido)tantalum, TAIMATA), (iPrN)Ta(NEt₂)₃(iso-propylimido tris(diethylamido)tantalum, IPTDET), Ta₂(OEt)₁₀(tantalum penta-ethoxide, TAETO), (Me₂NCH₂CH₂O)Ta(OEt)₄(dimethylaminoethoxy tantalum tetra-ethoxide, TATDMAE), and TaCl₅(tantalum pentachloride). Representative examples of Ti-containing precursors include Ti(NEt₂)₄(tetrakis(diethylamido)titanium, TDEAT), Ti(NMeEt)₄(tetrakis(ethylmethylamido)titanium, TEMAT), Ti(NMe₂)₄(tetrakis(dimethylamido)titanium, TDMAT), Ti(THD)₃(tris(2,2,6,6-tetramethyl-3,5-heptanedionato)titanium), and TiCl₄(titanium tetrachloride). Representative examples of W-containing precursors include W(CO)₆(tungsten hexacarbonyl), WF₆(tungsten hexafluoride), and (tBuN)₂W(NMe₂)₂(bis(tert-butylimido)bis(dimethylamido)tungsten, BTBMW). In the above precursor, the following abbreviations are used: Me: methyl; Et: ethyl; iPr: isopropyl; tBu: ter-butyl; and THD: 2,2,6,6-tetramethyl-3,5-heptanedionate. In some examples, a nitrogen-containing gas such as ammonia (NH₃) or hydrazine (N₂H₄) may be utilized as a source of nitrogen when depositing the metal nitride barrier film 12.

FIG. 1C schematically shows a Ru film 14 deposited on the metal nitride barrier film 12. A thickness of the Ru film 14 can, for example, be between about 0.5 nm and about 5 nm, or between about 1 nm and about 3 nm, for example about 2 nm. For example, the Ru film 14 may be deposited by a CVD process at a substrate temperature of about 180° C. utilizing a Ru₃CO₁₂ precursor and a CO carrier gas. An exemplary Ru CVD process using a Ru₃CO₁₂ precursor and a CO carrier gas is described U.S. patent application Ser. No. 10/996,145, entitled METHOD AND DEPOSITION SYSTEM FOR INCREASING DEPOSITION RATES OF METAL LAYERS FROM METAL-CARBONYL PRECURSORS, the entire content of which is herein incorporated by reference. In another example, the Ru film 14 may be deposited by a CVD process utilizing a ruthenium metalorganic precursor. Exemplary ruthenium metalorganic precursors include (2,4-dimethylpentadienyl)(ethylcyclopentadienyl)ruthenium(Ru(DMPD)(EtCp)), bis(2,4-dimethylpentadienyl)ruthenium(Ru(DMPD)₂), 4-dimethylpentadienyl) (methylcyclopentadienyl)ruthenium(Ru(DMPD)(MeCp)), and bis(ethylcyclopentadienyl)ruthenium(Ru(EtCp)₂), as well as combinations of these and other precursors. Other examples for depositing the Ru film 14 include sputtering methods using a solid Ru metal target.

According to one embodiment of the invention, the Ru film 14 may be heat treated at a temperature between about 200° C. and about 400° C. following deposition of the Ru film 14. During the heat treating, the Ru film 14 may be exposed to an inert gas, H₂, or a combination of an inert gas and H₂. The inert gas can, for example, be selected from a noble gas and N₂. A combination of an inert gas and H₂ can, for example, include a 10:1 H₂:Ar mixture. An exemplary heat treatment of the Ru film 14 includes a gas pressure of 3 Torr and process time of 30 minutes, but embodiments of the invention are not limited by these processing conditions as other heat treating conditions may be utilized. For example, the gas pressure can be between about 1 Torr and about 760 Torr. In some embodiments of the invention, the gas pressure can be between about 1 Torr and about 10 Torr.

FIG. 1D schematically shows a Cu seed layer 16 deposited on the Ru film 14. The Cu seed layer 16 provides a Cu growth surface for a subsequent Cu plating process. According to one embodiment of the invention, the Cu seed layer 16 may be deposited onto the Ru film 14 without heat treating the Ru film 14. According to another embodiment of the invention, the Cu seed layer 16 may be deposited on a Ru film 14 following the heat treatment of the Ru film 14 described above. A thickness of the Cu seed layer 16 can, for example, be between about 0.5 nm and about 5 nm, or between about 1 nm and about 3 nm, for example about 2 nm. The Cu seed layer 16 may be deposited by sputtering methods, for example by ionized physical vapor deposition (IPVD). An exemplary IPVD system is described in U.S. Pat. No. 6,287,435. According to one embodiment of the invention, the Ru film 14 may be exposed to an Ar plasma prior to sputter depositing the Cu seed layer 16. In one example, the Cu seed layer 16 may be deposited using a capacitively coupled plasma (CCP) system where a Cu sputtering target forms an upper electrode and a substrate holder upon which the substrate 10 is positioned forms a lower electrode. Using such a CCP system, the Ru film 14 may be exposed to the Ar plasma prior to sputter depositing the Cu seed layer 16 by biasing (DC or RF powering) the substrate holder while not biasing the upper electrode. However, other types of plasma systems can be used.

FIG. 1E schematically shows bulk Cu metal 18 formed on the Ru film 14. Bulk Cu metal deposition processes are well known by one of ordinary skill in the art of circuit fabrication and can, for example, include an electrochemical plating process or an electroless plating process. Commonly, bulk Cu metal deposition is followed by a chemical mechanical polishing (CMP) process to planarize and remove excess Cu metal. Other bulk Cu metal deposition processes are also available, for example Cu sputtering processes.

According to one embodiment of the invention, the bulk Cu metal 18 may be heat treated at a temperature between about 200° C. and about 400° C. following the Cu plating process. During the heat treating, the bulk Cu metal 18 may be exposed to H₂ or a combination of an inert gas and H₂. The inert gas can, for example, be selected from a noble gas and N₂. The combination of the inert gas and H₂ can, for example, include forming gas, which commonly contains 1-10% H₂ and balance N₂. Exemplary heat treatment of the bulk Cu metal 18 includes a gas pressure of 3 Torr, 3% H₂ in N₂, and a process time of 30 minutes, but embodiments of the invention are not limited by these heat treating conditions as other processing conditions may be utilized. For example, the gas pressure can be between about 1 Torr and about 760 Torr. In some embodiments of the invention, the gas pressure can be between about 1 Torr and about 10 Torr.

For comparison, conventional TaN/Ta/Cu film structures are commonly limited to heat treating temperatures of about 100-150° C. in the presence of forming gas, due to oxidation of the Ta film (e.g., by oxygen diffusion from a dielectric layer into the Ta film). Oxidation of the Ta film leads to poor adhesion to Cu and subsequently leads to electromigration and reliability problems in TaN/Ta/Cu film structures. The inventors of the current invention have realized that TaN/Ru/Cu films may be heat treated to temperatures between about 200° C. and about 400° C. following a Cu plating process, while providing good electromigration and reliability properties. It is contemplated that this is due to good adhesion of Ru and oxidized Ru films to Cu.

According to an embodiment of the invention, the Ru film 14, the bulk Cu metal 18, or both the Ru film 14 and the bulk Cu metal 18, may be heat treated in separate steps as described above. The heat treating steps may use the same or similar temperatures and gaseous environments, for example temperatures between about 350° C. and 400° C. and forming gas environments.

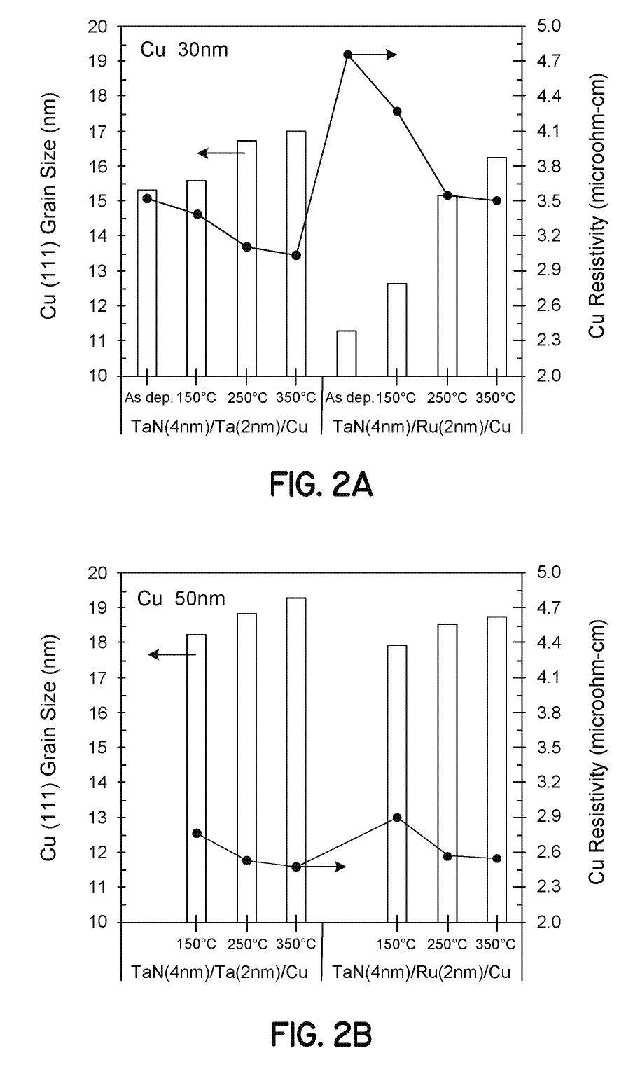

FIGS. 2A and 2B illustrate the relationship between Cu resistivity and Cu(111) grain size. FIG. 2A shows the relationship between Cu resistivity and Cu(111) grain size for TaN(4 nm)/Ta(2 nm)/(Cu(30 nm) and TaN(4 nm)/Ru(2 nm)/(Cu(30 nm) film structures as a function of heat treatments at different temperatures in forming gas (3% H₂) environments following bulk Cu metal deposition. The numbers in the parentheses refer to the thickness of each material, for example 4 nm TaN, 2 nm Ta, and 30 nm Cu. The Cu resistivity was measured using a 4-point probe and the Cu(111) grain size was calculated from X-ray diffraction (XRD) measurements using Scherrer's equation. The TaN and Ta films were deposited by IPVD and the Ru films were deposited by CVD at a substrate temperature of 180° C. using a Ru₃(CO)₁₂ precursor and CO carrier gas. The Cu seed layer was deposited by IPVD and the bulk Cu metal was electroplated onto the Cu seed layer. In FIG. 2A, measured Cu resistivities and calculated Cu(111) grain sizes are shown for as-deposited structures (no bulk Cu metal heat treating) and following bulk Cu metal heat treating at temperatures of 150° C., 250° C., and 350° C. The heat treating included exposure to forming gas (3% H₂) at a gas pressure of 650 Torr and a processing time of 30 minutes.

As mentioned in the Background of the Invention section, Cu metallization structures containing Ru films generally have higher Cu resistivity than those containing the traditional TaN/Ta bilayers. FIG. 2A clearly shows the difference in Cu(111) grain size and Cu resistivity between as-deposited TaN(4 nm)/Ta(2 nm)/Cu and TaN(4 nm)/Ru(2 nm)/Cu film structures. In order to study the effect of heat treating on Cu resistivity and Cu(111) grain size, the films structures were heat treated in the presence of 650 Torr of forming gas for 30 minutes at substrate temperatures of 150° C., 250° C., and 350° C. FIG. 2A shows a large increase in Cu(111) grain size and a large reduction in Cu resistivity for the TaN(4 nm)/Ru(2 nm)/Cu film structures, but the effects are smaller for the TaN(4 nm)/Ta(2 nm)/Cu film structures. At the highest heat treating temperature (350° C.) studied, the Cu resistivity and the Cu(111) grain size of the TaN(4 nm)/Ru(2 nm)/Cu film structure are comparable to that of the TaN(4 nm)/Ta(2 nm)/Cu film structure.

FIG. 2B shows the Cu resistivity and Cu(111) grain size for film structures with thicker Cu films (50 nm) than in FIG. 2A. The results in FIG. 2B show the same trends for the Cu resistivity and Cu(111) grain size as FIG. 2A, but the effects of heat treating are smaller for the thicker Cu films in FIG. 2B.

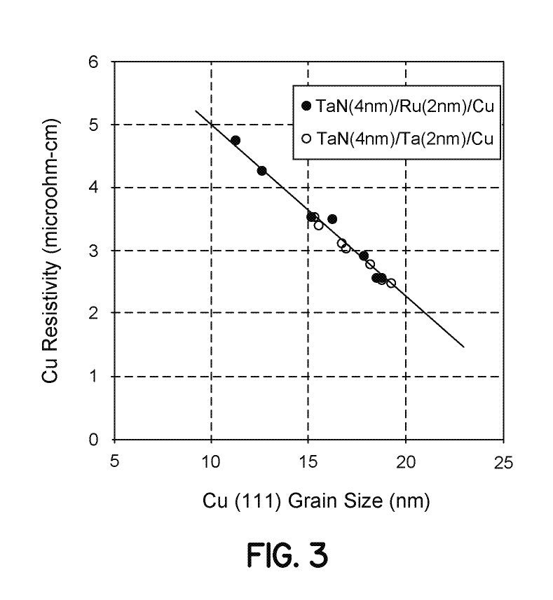

FIG. 3 summarizes the Cu resistivity and Cu(111) grain size results from FIGS. 2A and 2B. Good linear relationship is observed between Cu resistivity and Cu(111) grain size, where increased Cu(111) grain size reduces Cu resistivity.

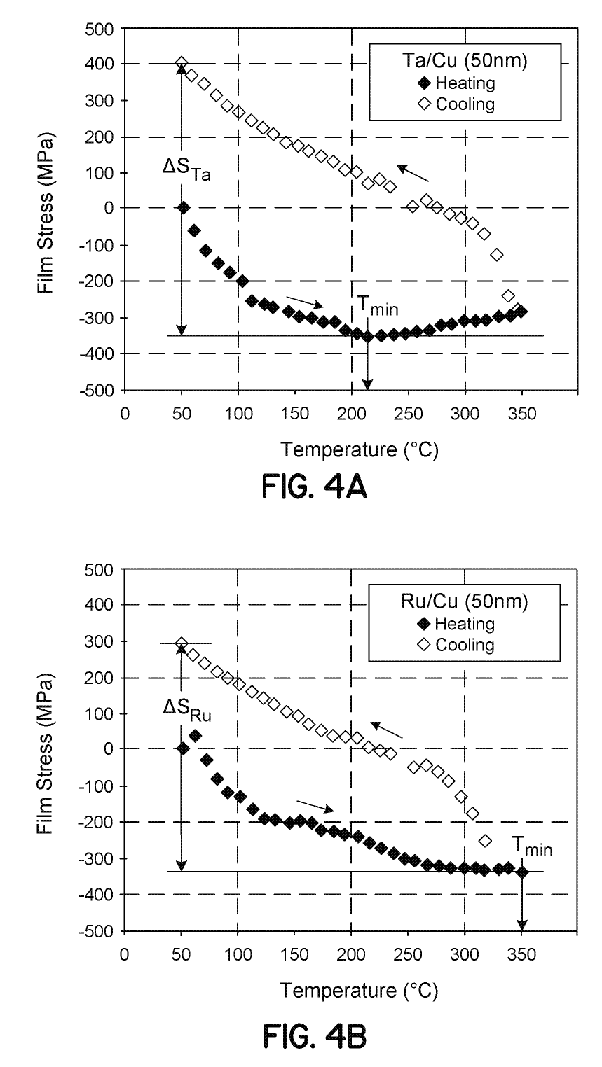

FIGS. 4A and 4B show Ta/Cu and Ru/Cu film stress versus temperature. The stress behavior of the Ta/Cu and Ru/Cu film structures (Cu thickness 50 nm) was measured in vacuum for temperature ramps from 50° C. to 350° C. to determine the effect of heat treating on film stress. Comparison of FIGS. 4A and 4B shows that the Ru/Cu film structure reached minimum film stress at a higher temperature (Tₘᵢₙ=350° C.) than the Ta/Cu film structure (Tₘᵢₙ=225° C.). This suggests that a Cu film may have higher surface energy on a Ru film than on a Ta film, thereby requiring heat treating the Ru/Cu film structure to a higher temperature than is required for the Ta/Cu film structure in order to release surface and film stress by atomic restructuring. This difference in temperature is believed to be due to a smaller lattice misfit δ (δ=(d_{cu}-d_{sub})/d_{sub}, where d_{sub} is interplanar spacing of Ta or Ru atoms, between Ru(002) or Ru(111) and Cu(111) crystallographic planes than between Ta(110) and Cu(111) crystallographic planes. The results in FIGS. 4A and 4B are believed to explain the stronger effect of heat treating on Cu resistivity for the TaN/Ru/Cu film structures than for the TaN/Ta/Cu structures in FIGS. 2A and 2B.

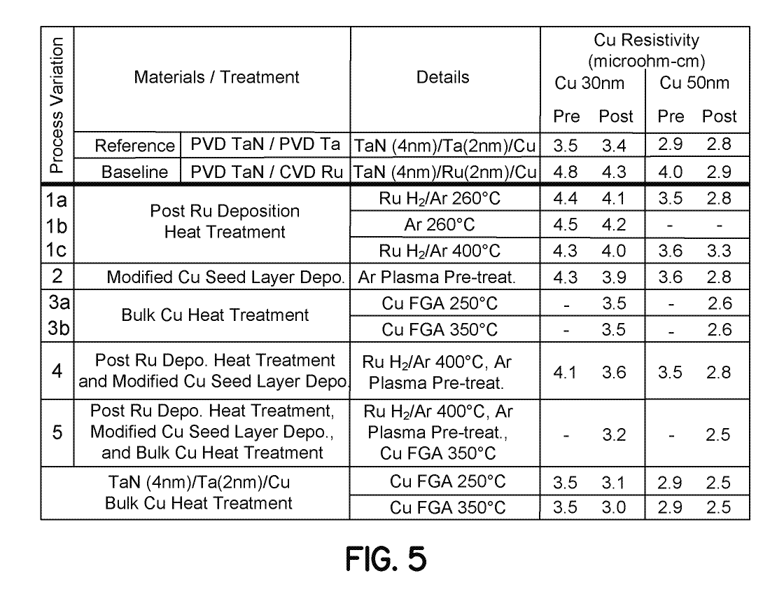

FIG. 5 shows resistivity of bulk Cu films in tabular form for different film structures, including 30 nm and 50 nm thick bulk Cu films in TaN(4 nm)/Ru(2 nm)/Cu film structures for different process variations. The Cu resistivity results for the different process variations are compared to TaN(4 nm)/Ta(2 nm)/Cu reference structures and TaN(4 nm)/Ru(2 nm)/Cu baseline structures to evaluate the effectiveness of different process variations. In FIG. 5, “Pre” and “Post” refer to measured Cu resistivity before and after heat treating the bulk Cu metal films in H₂/Ar or forming gas (forming gas anneals (FGA)) at a substrate temperature of 150° C. For process variations 3a, 3b, and 5, “Post” refers to heat treating of the bulk Cu metal films in H₂/Ar or forming gas at the indicated temperatures (i.e., 250° C. or 350° C.).

The different process variations in FIG. 5 will now be described. Process variations 1a-1c show the effect of different post Ru deposition heat treatments (heat treating of a deposited Ru film prior to Cu seed layer deposition) for: 1a) exposure to 10:1 H₂/Ar (500 sccm H₂ and 50 sccm Ar) gas at a substrate temperature of 260° C.; 1b) exposure to Ar gas at a substrate temperature of 260° C.; and 1c) exposure to 10:1 H₂/Ar gas at a substrate temperature of 400° C. The post Ru deposition heat treatments were performed at gas pressures of 3 Torr for 30 minutes. Process variation 2 shows the effect of modified Cu seed layer deposition where the modification included exposing the Ru film to Ar plasma prior to Cu seed layer deposition. Process variation 3 shows the effect of bulk Cu heat treatments for: 3a) exposure to forming gas at a substrate temperature of 250° C.; and 3b) exposure to forming gas at a substrate temperature of 350° C. The bulk Cu heat treatments were performed at gas pressures of 650 Torr for 30 minutes. Process variation 4 shows the combined effects of post Ru deposition heat treatment in 10:1 H₂:Ar gas at 400° C. and modified Cu seed layer deposition described above. Process variation 5 shows the combined effects of post Ru deposition heat treatment in 10:1 H₂:Ar gas at 400° C., modified Cu seed layer deposition, and bulk Cu film heat treatment at 350° C. in forming gas. In addition, FIG. 5 shows the effect of bulk Cu heat treatments at 250° C. and 350° C. on the TaN(4 nm)/Ta(2 nm)/Cu reference structures.

FIG. 5 shows that Cu resistivities for the TaN(4 nm)/Ru(2 nm)/Cu baseline structures are higher than for the TaN(4 nm)/Ta(2 nm)/Cu reference structures, both before and after Cu heat treatments at 150° C. Furthermore, FIG. 5 shows that the different process variations are effective in reducing Cu resistivities from that of the TaN(4 nm)/Ru(2 nm)/Cu baseline structures to values that are comparable or equal to the Cu resistivity values measured for the TaN(4 nm)/Ta(2 nm)/Cu reference structures. For example, process variation 5 results in Cu resistivity of 3.2 microohm-cm for the TaN(4 nm)/Ru(2 nm)/Cu(30 nm) structure and 2.5 microohm-cm for the TaN(4 nm)/Ru(2 nm)/Cu(50 nm) structure. These values are comparable or equal to the TaN(4 nm)/Ta(2 nm)/Cu reference structures for 30 nm and 50 nm thick bulk Cu films. FIG. 5 further shows that heat treating of the bulk Cu is the most effective parameter in reducing Cu resisitivity.

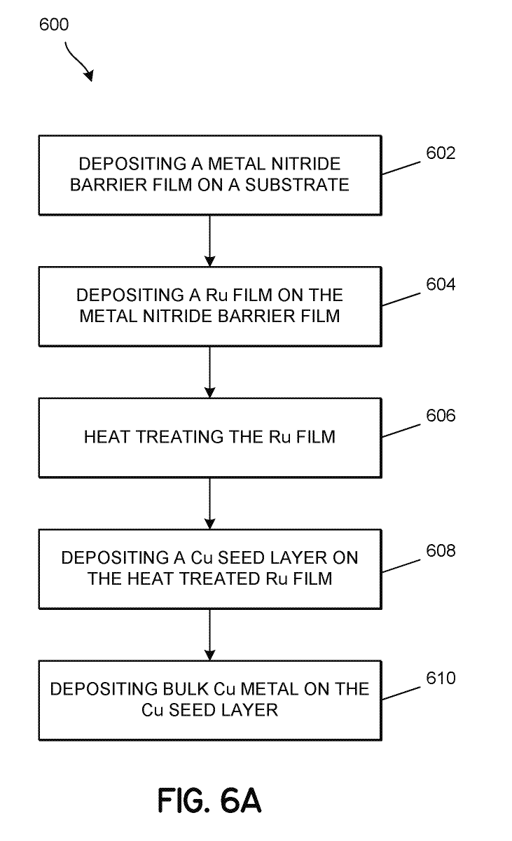

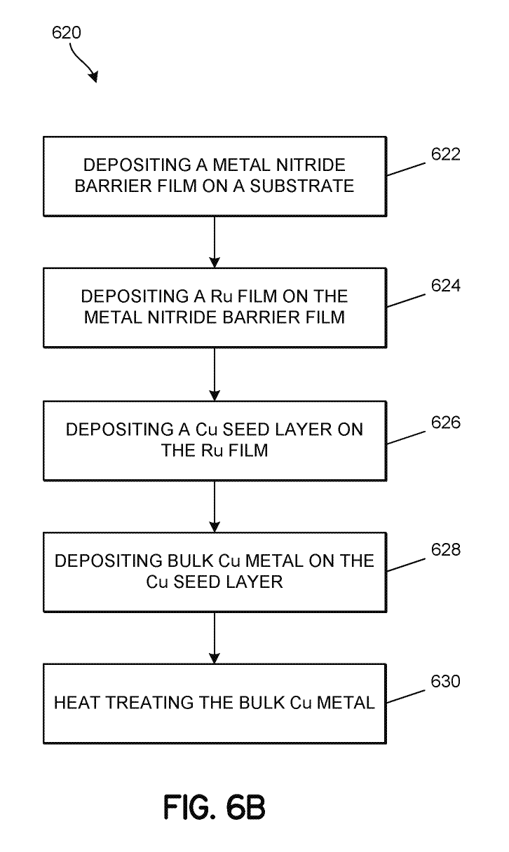

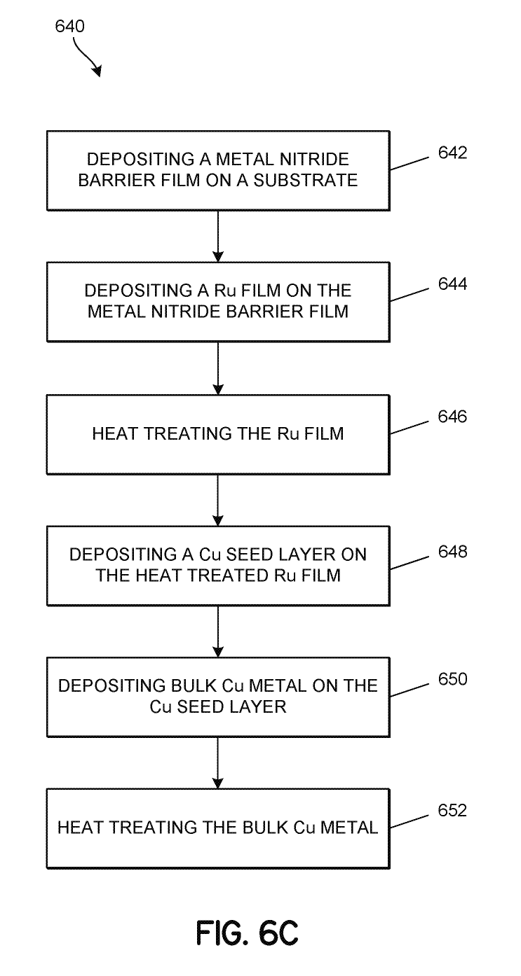

FIGS. 6A-6C are process flow diagrams for forming low resistivity Cu film structures according to embodiments of the invention. The steps of the process flow diagrams in FIGS. 6A-6C have been described above. It should be noted that in this application, the term “step” does not prohibit two steps from being performed simultaneously or partially overlapping in time. For example, Ru deposition and heat treating steps may be performed simultaneously or partially overlap in time.

In FIG. 6A, the process 600 includes: in step 602, depositing a metal nitride barrier film on a substrate; in step 604, depositing a Ru film on the metal nitride barrier film; in step 606, heat treating the Ru film; in step 608, depositing a Cu seed layer on the heat treated Ru film; and in step 610, depositing bulk Cu metal on the Cu seed layer.

In FIG. 6B, the process 620 includes: in step 622, depositing a metal nitride barrier film on a substrate; in step 624, depositing a Ru film on the metal nitride barrier film; in step 626, depositing a Cu seed layer on the Ru film; in step 628, depositing bulk Cu metal on the Cu seed layer; and in step 630, heat treating the bulk Cu metal.

In FIG. 6C, the process 640 includes: in step 642, depositing a metal nitride barrier film on a substrate; in step 644, depositing a Ru film on the metal nitride barrier film; in step 646, heat treating the Ru film; in step 648, depositing a Cu seed layer on the heat treated Ru film; in step 650, depositing bulk Cu metal on the Cu seed layer; and in step 652, heat treating the bulk Cu metal.

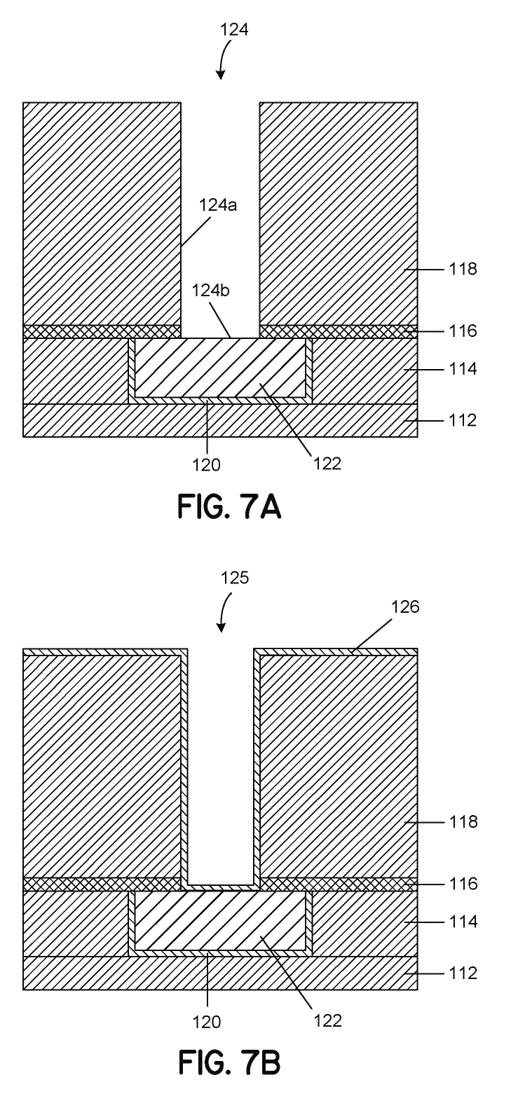

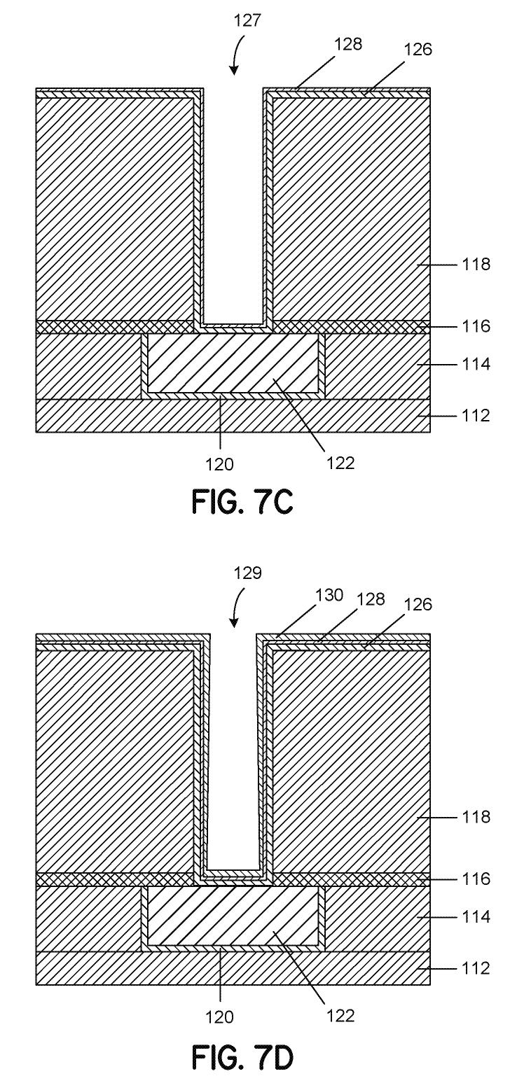

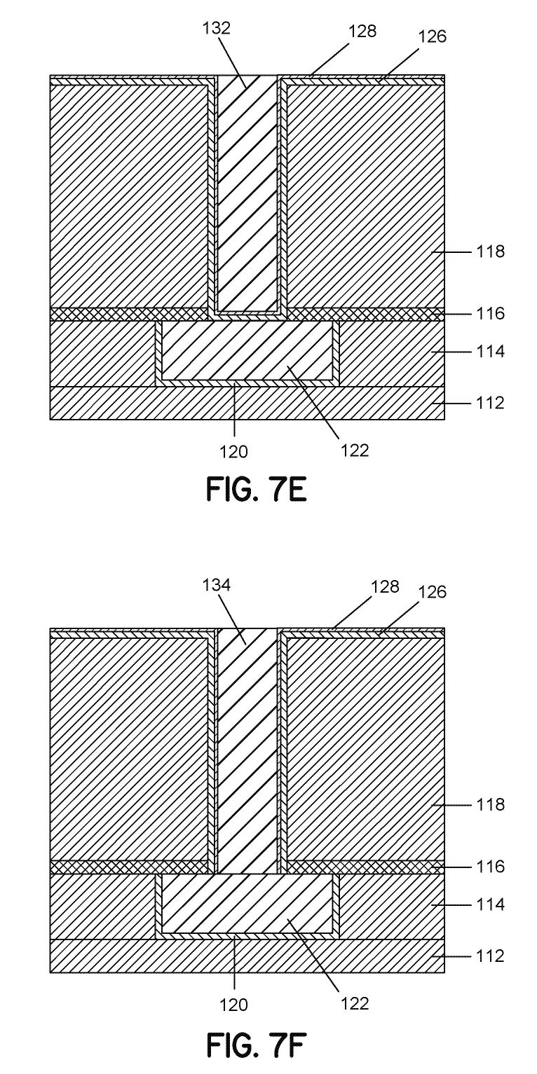

FIGS. 7A-7F schematically show cross-sectional views for forming low resistivity Cu interconnect structures according to embodiments of the invention. FIG. 7A schematically shows a cross-sectional view of an interconnect structure having a micro-feature opening 124 formed in dielectric material 118 over a conductive interconnect structure 122. The micro-feature opening 124 includes sidewall and bottom surfaces 124a and 124b, respectively. The interconnect structure further contains dielectric layers 112 and 114, a barrier layer 120 surrounding the conductive interconnect structure 122, and an etch stop layer 116. The conductive interconnect structure 122 can, for example, contain Cu or tungsten (W).

According to an embodiment of the invention, the micro-feature opening 124 can be a via having an aspect ratio (depth/width) greater than or equal to about 2:1, for example 3:1, 4:1, 5:1, 6:1, 12:1, 15:1, or higher. The via can have a width of about 200 nm or less, for example 150 nm, 100 nm, 65 nm, 32 nm, 22 nm, or less. However, embodiments of the invention are not limited to these aspect ratios or via widths, as other aspect ratios and via widths may be utilized.

In FIG. 7B, a metal nitride barrier film 126 is deposited on the interconnect structure, including on the sidewall and bottom surfaces 124a and 124b of the micro-feature opening 124 to form micro-feature opening 125. The metal nitride barrier film 126 can, for example, contain TaN, TiN, or WN, or combinations thereof. A thickness of the metal nitride barrier film 12 can, for example, be between about 1 nm and about 10 nm, or between about 2 nm and about 5 nm, for example about 4 nm.

In FIG. 7C, a Ru film 128 is deposited on the metal nitride barrier film 126 to form micro-feature opening 127. A thickness of the Ru film 128 can, for example, be between about 0.5 nm and about 5 nm, or between about 1 nm and about 3 nm, for example about 2 nm.

According to one embodiment of the invention, the Ru film 128 may be heat treated at a temperature between about 200° C. and about 400° C. During the heat treating, the Ru film 128 may be exposed to an inert gas, H₂, or a combination of an inert gas and H₂. The inert gas can, for example, be selected from Ar and N₂. The combination of the inert gas and H₂ can, for example, be 10:1 H₂:Ar. Exemplary heat treatments of the Ru film 128 include gas pressure of 3 Torr and process time of 30 minutes. Other heat treatments of the Ru film 128 can, for example, include gas pressure between about 1 Torr and about 760 Torr.

In FIG. 7D, a Cu seed layer 130 is deposited over the interconnect structure to form micro-feature opening 129. The Cu seed layer 130 may be non-conformally deposited over the interconnect structure with a minimum thickness on the sidewalls of the micro-feature. The Cu seed layer 130 may be utilized as a Cu growth surface for a subsequent Cu plating process. According to one embodiment of the invention, the Cu seed layer 130 may be deposited on a Ru film 128 following a heat treatment of the Ru film 128 described above. A thickness of the Cu seed layer 130 can be between about 0.5 nm and about 5 nm, or between about 1 nm and about 3 nm, for example about 2 nm.

In FIG. 7E, the micro-feature opening 129 is filled with bulk Cu metal 132 and excess Cu metal removed from the interconnect structure by a CMP process. Although not shown in FIG. 7E, the CMP process may at least partially remove the Ru film 128 and the metal nitride barrier film 126 from the field area of the interconnect structure.

According to another embodiment of the invention, the Ru film 128 and the metal nitride barrier film 126 at the bottom of the micro-feature opening 127 depicted in FIG. 7C may be at least partially removed by a sputter removal process prior to deposition of the Cu seed layer 130, in order to reduce the resistivity between the bulk Cu metal and the conductive interconnect structure 122. FIG. 7F shows an interconnect structure where the Ru film 128 and the metal nitride barrier film 126 at the bottom of the micro-feature opening 127 have been completely removed prior to deposition of the Cu seed layer 130 and the bulk Cu metal 134, thereby directly contacting the bulk Cu metal 134 and the conductive interconnect structure 122, which reduces the resistivity of the interconnect structure in FIG. 7F compared to that of the interconnect structure depicted in FIG. 7E. Although not shown in FIG. 7F, removal of the metal nitride barrier film 126 from the bottom of the micro-feature may at least partially remove the Ru film 128 and the metal nitride barrier film 126 from other surfaces of the interconnect structure, such as the field area and sidewalls of the micro-feature.

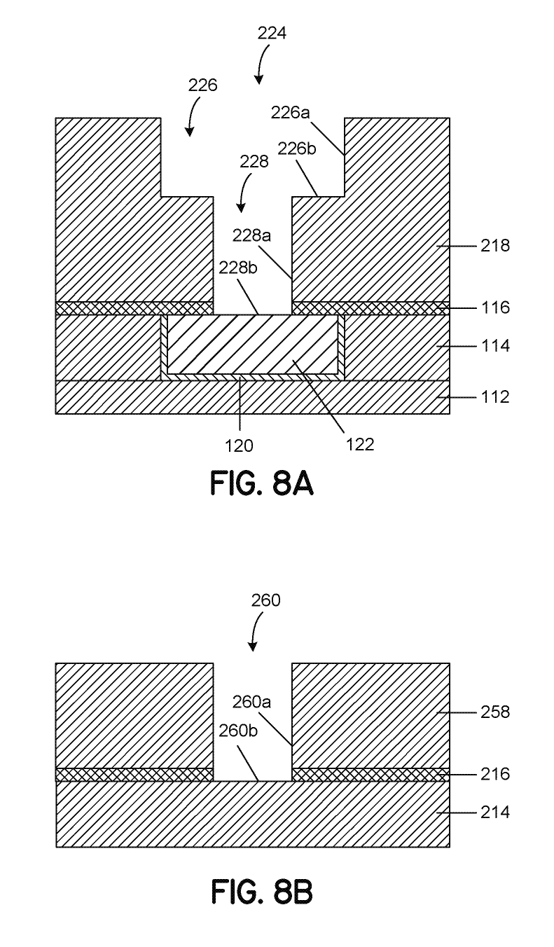

An exemplary micro-feature opening 124 was illustrated and described above in FIG. 7A, but embodiments of the invention may be applied to other types of micro-feature openings found in integrated circuit design. FIGS. 8A-8B schematically show cross-sectional views of other micro-feature openings according to additional embodiments of the invention. As will be appreciated by one of ordinary skill in the art, embodiments of the invention can be readily applied to the micro-feature openings depicted in FIGS. 8A and 8B.

FIG. 8A schematically shows a cross-sectional view of a dual damascene interconnect structure. Dual damascene interconnects are well known by one of ordinary skill in the art of integrated circuit fabrication. The interconnect structure depicted in FIG. 8A is similar to the interconnect structure depicted in FIG. 7A but contains a dual damascene interconnect opening 224 formed over conductive interconnect structure 122. The dual damascene interconnect opening 224 contains a via 228 having sidewall and bottom surfaces 228a and 228b, respectively, and a trench 226 formed in dielectric material 218, where the trench 226 contains sidewall and bottom surfaces 226a and 226b, respectively. The trench 226 may be used for an upper conductive interconnect structure and the via 228 connects the trench 226 to the conductive interconnect structure 122. The interconnect structure further contains dielectric layers 112 and 114, barrier layer 120 surrounding the conductive interconnect structure 122, and etch stop layer 116.

FIG. 8B schematically shows a cross-sectional view of an interconnect structure according to one embodiment of the invention. The interconnect structure contains a micro-feature opening (e.g., a trench) 260 within dielectric material 258. The micro-feature opening 260 includes sidewall and bottom surfaces 260a and 260b, respectively. The interconnect structure further contains dielectric layer 214 and etch stop layer 216.

Although only certain exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

It should be apparent from the discussion above, embodiments of the invention can provide film structures containing TaN/Ru/Cu films and having Cu resistivity that is comparable or equal to conventional TaN/Ta/Cu film structures. Furthermore, unlike Ta films, Ru films may be conformally deposited to meet current and future requirements of high aspect ratio structures in integrated circuits. Still further, TaN/Ru/Cu film structures may be annealed to higher temperatures than corresponding TaN/Ta/Cu film structures while providing good electromigration and reliability properties.

What is claimed is:

1. A method for forming a low resistivity Cu film structure, the method comprising:
depositing a metal nitride barrier film on a substrate;
depositing a Ru film on the metal nitride barrier film;
heat treating the Ru film at a first temperature between about 200° C. and about 400° C. in the presence of a first inert gas, H₂ gas, or a combination of the first inert gas and H₂ gas;
depositing a Cu seed layer on the heat treated Ru film; and
depositing bulk Cu metal on the Cu seed layer.

2. The method of claim 1, wherein the first inert gas comprises a noble gas or N₂.

3. The method of claim 1, further comprising:
heat treating the bulk Cu metal at a second temperature between about 200° C. and about 400° C. in the presence of H₂ gas or a combination of a second inert gas and H₂ gas.

4. The method of claim 3, wherein the second inert gas comprises a noble gas or N₂.

5. The method of claim 1, wherein the depositing a Cu seed layer comprises:
sputter depositing Cu metal.

6. The method of claim 5, wherein the depositing a Cu seed layer further comprises:
exposing the Ru film to an Ar plasma prior to the sputter depositing.

7. The method of claim 1, wherein the metal nitride barrier film comprises TaN, TiN, or WN, or a combination thereof.

8. The method of claim 1, wherein the substrate comprises a micro-feature opening formed within a dielectric material, and wherein the depositing bulk Cu metal comprises filling the micro-feature opening with the bulk Cu metal.

9. The method of claim 8, wherein the micro-feature opening comprises a via, a trench, or a combination thereof.

10. The method of claim 8, further comprising:
at least partially removing the metal nitride barrier film and the Ru film from a bottom surface of the micro-feature opening prior to the filling.

11. A method for forming a low resistivity Cu film structure, the method comprising:
depositing a metal nitride barrier film on a substrate;
depositing a Ru film on the metal nitride barrier film;
depositing a Cu seed layer on the Ru film;
depositing bulk Cu metal on the Cu seed layer; and
heat treating the bulk Cu metal at a temperature between about 200° C. and about 400° C. in the presence of H₂ gas or a combination of an inert gas and H₂ gas.

12. The method of claim 11, wherein the inert gas comprises a noble gas or N₂.

13. The method of claim 11, wherein the depositing a Cu seed layer comprises:
sputter depositing Cu metal.

14. The method of claim 13, wherein the depositing a Cu seed layer further comprises:
exposing the Ru film to an Ar plasma prior to the sputter depositing.

15. The method of claim 11, wherein the metal nitride barrier film comprises TaN, TiN, or WN, or a combination thereof.

16. The method of claim 11, wherein the substrate comprises a micro-feature opening formed within a dielectric material, and wherein the depositing bulk Cu metal comprises filling the micro-feature opening with the bulk Cu metal.

17. The method of claim 16, wherein the micro-feature opening comprises a via, a trench, or a combination thereof.

18. The method of claim 16, further comprising:
at least partially removing the metal nitride barrier film and the Ru film from a bottom surface of the micro-feature opening prior to the filling.

19. A method for forming a low resistivity Cu interconnect structure, the method comprising:
providing a substrate containing a micro-feature opening formed within a dielectric material;
depositing a metal nitride barrier film on the substrate, the metal nitride barrier film comprising TaN, TiN, or WN, or a combination thereof;
depositing a Ru film on the metal nitride barrier film;
depositing a Cu seed layer on the Ru film by sputter depositing;
filling the micro-feature opening with bulk Cu metal; and
heat treating the bulk Cu metal at a first temperature between about 200° C. and about 400° C. in the presence of H₂ gas or a combination of H₂ gas and a first inert gas comprising a first noble gas or N₂.

20. The method of claim 19, further comprising:
heat treating the Ru film at a second temperature between about 200° C. and about 400° C. in the presence of a second inert gas comprising a second noble gas or N₂, H₂ gas, or a combination of the second inert gas and H₂ gas, prior to depositing the Cu seed layer.

21. The method of claim 19, wherein the depositing a Cu seed layer further comprises:
exposing the Ru film to an Ar plasma prior to the sputter depositing 22. The method of claim 19, further comprising:
at least partially removing the metal nitride barrier film and the Ru film from a bottom surface of the micro-feature opening prior to the filling.
